(19) United States
(12) Patent Application Publication
(10) Pub. No.: US 2010/0216296 A1
(43) Pub. Date: Aug. 26, 2010

(54) Processing Method and Recording Medium

(76) Inventors: Yusuke Muraki, Yamanashi (JP); Shigeki Tozawa, Yamanashi (JP); Takehiko Orii, Yamanashi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/084,132

(22) PCT Filed: Oct. 20, 2006
(86) PCT No.: PCT/JP2006/320928

§ 371 Date: Apr. 25, 2008

(30) Foreign Application Priority Data
Oct. 27, 2005 (JP) 2005-312608

(51) Int. Cl. H01L 21/20; H01L 21/306

(52) U.S. Cl. 438/478; 438/706; 257/E21.09; 257/E21.215

(57) ABSTRACT

[Object] To provide a processing method capable of removing an oxide film adhering on a Si layer from the Si layer without adversely affecting parts other than the oxide film and capable of surely forming a SiGe layer with good film quality without roughening the crystal structure of a surface of the Si layer from which the oxide film has been removed, and to provide a recording medium.

[Means for Solving the Problems] A processing method for removing an oxide film growing on a surface of a Si layer, and forming a SiGe layer on the surface of the exposed Si layer includes: supplying gas containing a halogen element and basic gas to the surface of the Si layer, and causing the oxide film growing on the surface of the Si layer to chemically react with the gas containing the halogen element and the basic gas to turn the oxide film into a reaction product; removing the reaction product by heating; and thereafter forming the SiGe layer on the surface of the exposed Si layer.

### TECHNICAL FIELD

The present invention relates to a method of forming a SiGe layer in manufacturing processes of, for example, a semiconductor device.

### BACKGROUND ART

As a structure of a semiconductor device such as, for example, a transistor, there has been known a structure in which a strained Si layer, an interlayer insulation layer (silicon dioxide (SiO2)), and a gate electrode (polysilicon) are stacked on a surface of a Si (silicon) layer of a semiconductor wafer. Further, a process of forming a SiGe (silicon germanium) crystal layer on the surface of the Si layer is performed (see Patent document 1). Such a SiGe layer is formed by an epitaxial growth reaction, a CVD (Chemical Vapor Deposition) reaction, or the like.

On the surface of the Si layer exposed to the outside air, a natural oxide film (SiO2) easily grows, and the presence of the natural oxide film poses a problem of obstructing the formation of the SiGe layer. Conventionally, the wafer is cleaned by a wet cleaning process using a chemical solution such as DHF (dilute hydrofluoric acid), thereby removing the natural oxide film from the surface of the Si layer before the SiGe layer is formed.

[Patent Document 1] Japanese Patent Application Laid-open No. 2001

### DISCLOSURE OF THE INVENTION

### Problems to be Solved by the Invention

However, in the wet cleaning using DHF, there is a concern that parts other than the natural oxide film may be adversely affected due to relatively high selection ratios (etching rates) of materials other than the natural oxide film. For example, if sidewall portions (sidewalls) made of TEOS (tetraethylorthosilicate) or the like are formed on side surfaces of the gate electrode, there has been a problem that these sidewall portions are etched by DHF to be damaged.

Further, if the natural oxide film is removed by the wet cleaning using DHF, the crystal structure of the surface of the Si layer becomes rough to adversely affect the crystal of the SiGe layer when the SiGe layer is grown.

The present invention was made in view of the above problems, and its object is to provide a processing method capable of removing an oxide film adhering to a Si layer from the Si layer without adversely affecting parts other than the oxide film and capable of surely forming a SiGe layer with good film quality without roughening the crystal structure of a surface of the Si layer from which the oxide film has been removed, and to provide a recording medium.

### Means for Solving the Problems

To solve the aforesaid problems, according to the present invention, there is provided a processing method for removing an oxide film growing on a surface of a Si layer, and forming a SiGe layer on the surface of the exposed Si layer, the method comprising: supplying gas containing a halogen element and basic gas to the surface of the Si layer, and causing the oxide film growing on the surface of the Si layer to chemically react with the gas containing the halogen element and the basic gas to turn the oxide film into a reaction product; removing the reaction product by heating; and thereafter forming the SiGe layer on the surface of the exposed Si layer. Further, according to the present invention, there is provided a processing method for removing an oxide film growing on a surface of a Si layer when a SiGe layer is to be formed on the surface of the Si layer, the method comprising: supplying gas containing a halogen element and basic gas to the surface of the Si layer, and causing the oxide film growing on the surface of the Si layer to chemically react with the gas containing the halogen element and the basic gas to turn the oxide film into a reaction product; and removing the reaction product by heating. Further, according to the present invention, there is provided a processing method for removing an oxide film growing on a surface of a Si layer, and forming a SiGe layer on the surface of the exposed Si layer, the method comprising: removing part of the oxide film growing on the surface of the Si layer by wet etching using a treatment solution; supplying gas containing a halogen element and basic gas to a remaining part of the oxide film the part of which has been removed by the wet etching, and causing the remaining part of the oxide film to chemically react with the gas containing the halogen element and the basic gas to turn the remaining part of the oxide film into a reaction product; removing the reaction product by heating; and thereafter forming the SiGe layer on the surface of the exposed Si layer.

Here, the process of causing the oxide film to chemically react with the gas containing the halogen element and the basic gas is a COR (Chemical Oxide Removal) process (process of chemically removing an oxide), for instance. In the COR process, the gas containing the halogen element and the basic gas are supplied as process gases to a wafer to cause the oxide film adhering on the wafer to chemically react with gas molecules of the process gases, thereby producing the reaction product. The gas containing the halogen element is hydrogen fluoride vapor (HF), for instance, and the basic gas is ammonia vapor (NH₃), for instance. In this case, a reaction product mainly containing ammonium fluosilicate ((NH₄)2SiF₆) is produced.

The process of removing the reaction product by heating is a PHT (Post Heat Treatment) process, for instance. The PHT process is a process of vaporizing (sublimating) the reaction product such as ammonium fluosilicate by heating the wafer having undergone the COR process.

In this processing method, part of the Si layer may be exposed in advance by dry-etching an interlayer insulation layer after the formation of the interlayer insulation layer on the Si layer. Further, a gate electrode may be formed on the interlayer insulation layer. Further, a sidewall portion may be formed on a side surface of the gate electrode.

The gas containing the halogen element is hydrogen fluoride gas (HF), for instance, and the basic gas is ammonia gas (NH₃), for instance. In this case, the hydrogen fluoride gas may be supplied at not lower than 20 sccm nor higher than 200 sccm. “sccm” means cc(cm³)/min under the condition of 1 atm (1.01352×10⁵ Pa) and 0° C. The ammonia gas may be supplied at not lower than 20 sccm nor higher than 200 sccm. Further, in the process of causing the chemical reaction, argon gas may be supplied at 600 sccm or lower, or nitrogen gas may be supplied at 600 sccm or lower.

Pressure of a processing space where the process of causing the chemical reaction is performed may be not lower than 1.333 Pa nor higher than 5.333 Pa (not lower than 10 mTorr nor higher than 40 mTorr). Temperature of the Si layer may be not lower than 20° C. nor higher than 40° C. in the process of causing the chemical reaction. Processing time for the chemical reaction may be not shorter than 15 seconds nor longer than 300 seconds.

Further, according to the present invention, there is provided a recording medium in which a program executable by a control computer of a substrate processing apparatus is recorded, the program causing the substrate processing apparatus to perform the substrate processing method according to the present invention when executed by the control computer.

### EFFECT OF THE INVENTION

According to the present invention, it is possible to remove an oxide film from a Si layer without adversely affecting parts other than the oxide film and to surely form a SiGe layer with good film quality on the Si layer without roughening the crystal structure on a surface of the Si layer from which the oxide film has been removed.

### BRIEF DESCRIPTION OF THE DRAWINGS

FIG. 1 A rough vertical sectional view showing the structure of a surface of a wafer before a Si layer is etched.

FIG. 2 A rough vertical sectional view showing the structure of the surface of the wafer after the Si layer is etched.

FIG. 3 A rough plane view of a processing system.

FIG. 4 A rough vertical sectional view showing the structure of a COR apparatus.

FIG. 5 A rough vertical sectional view showing the structure of a PHT apparatus.

FIG. 6 A rough vertical sectional view showing a state of the surface of the wafer having undergone a COR process.

FIG. 7 A rough vertical sectional view showing a state of the surface of the wafer having undergone a PHT process.

FIG. 8 A rough vertical sectional view showing a state of the surface of the wafer having undergone a SiGe layer forming process.

FIG. 9 An explanatory view of a system group performing the combination of wet etching using a treatment solution and a dry cleaning process including the COR process and the PHT process.

FIG. 10 A rough vertical sectional view showing a state of the surface of the wafer from which parts of natural oxide films growing on a surface of the Si layer have been removed by wet etching.

FIG. 11 An explanatory view of a processing system in which six processing apparatuses are provided around a common transfer chamber.

FIG. 12 An explanatory view of a processing system in which a wafer is carried into a COR apparatus from a load/unload unit via a load lock chamber and a PHT apparatus.

FIG. 13 A graph showing selection ratios of various materials in dry cleaning.

FIG. 14 A table showing an example of various conditions in the COR process.

### EXPLANATION OF CODES

1 processing system
5 COR apparatus
6 PHP apparatus
32 processing chamber
33 processing chamber
51 supply path of hydrogen fluoride gas
52 supply path of ammonia gas

### BEST MODE FOR CARRYING OUT THE INVENTION

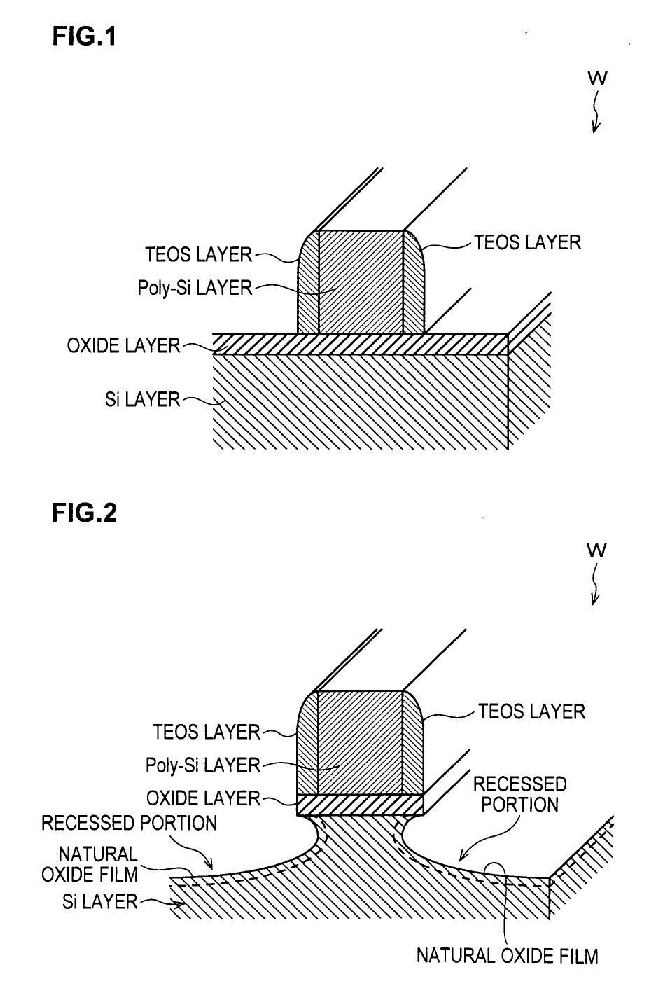

Hereinafter, a preferred embodiment of the present invention will be described. First, the structure of a wafer as a substrate processed by a processing method according to this embodiment will be described. In the specification and drawings, constituent elements having substantially the same functions and structures will be denoted by the same reference symbols and redundant description thereof will be omitted. FIG. 1 is a rough vertical sectional view of a wafer W which has not yet undergone an etching process, showing part of a surface (device formation surface) of the wafer W. The wafer W is, for example, a thin-plate silicon wafer formed in a substantially disk shape, and on its surface, formed is a structure composed of a Si (silicon) layer as a base material of the wafer W, an oxide layer (silicon dioxide: SiO₂) used as an interlayer insulation layer, a Poly-Si (polycrystalline silicon) layer used as a gate electrode, and, for example, TEOS (tetraethylorthosilicate: Si(OC₂H₅)₄) layers as sidewall portions (sidewalls) made of an insulator. A surface (upper surface) of the Si layer is substantially flat, and the oxide layer is stacked to cover the surface of the Si layer. The oxide layer is formed through a CVD reaction by, for example, a plasma CVD apparatus. The Poly-Si layer is formed on a surface of the oxide layer and is etched along a predetermined pattern. Therefore, some portions of the oxide layer are covered by the Poly-Si layer, and the other portions thereof are exposed. The TEOS layers are formed to cover side surfaces of the Poly-Si layer. In the shown example, the Poly-Si layer has a substantially quadrangular cross section and is formed in a long and thin prismatic shape extending in a direction from the near side toward the far side in FIG. 1, and the TEOS layers are provided on right and left side surfaces of the Poly-Si layer to extend along the direction from the near side toward the far side and to cover the Poly-Si layer from its lower edge to upper edge. On the right and left sides of the Poly-Si layer and the TEOS layers, the surface of the oxide layer is exposed.

FIG. 2 shows a state of the wafer W having undergone the etching process. After the oxide layer, the Poly-Si layer, the TEOS layers, and so on are formed on the Si layer as shown in FIG. 1, the wafer W is, for example, dry-etched. Consequently, as shown in FIG. 2, on the surface of the wafer W, exposed parts of the oxide layer and parts of the Si layer covered by these parts of the oxide layer are removed. Specifically, on the right and left sides of the Poly-Si layer and the TEOS layers, recessed portions are formed respectively by the etching. The recessed portions are formed so as to sink into the Si layer from the height of the surface of the oxide layer, and the Si layer is exposed on surfaces of the recessed portions. If oxygen in the atmosphere adheres to the surface of the Si thus exposed in the recessed portions, natural oxide films (silicon dioxide: SiO₂) are formed on inner surfaces of the recessed portions since the Si layer is easily oxidized.

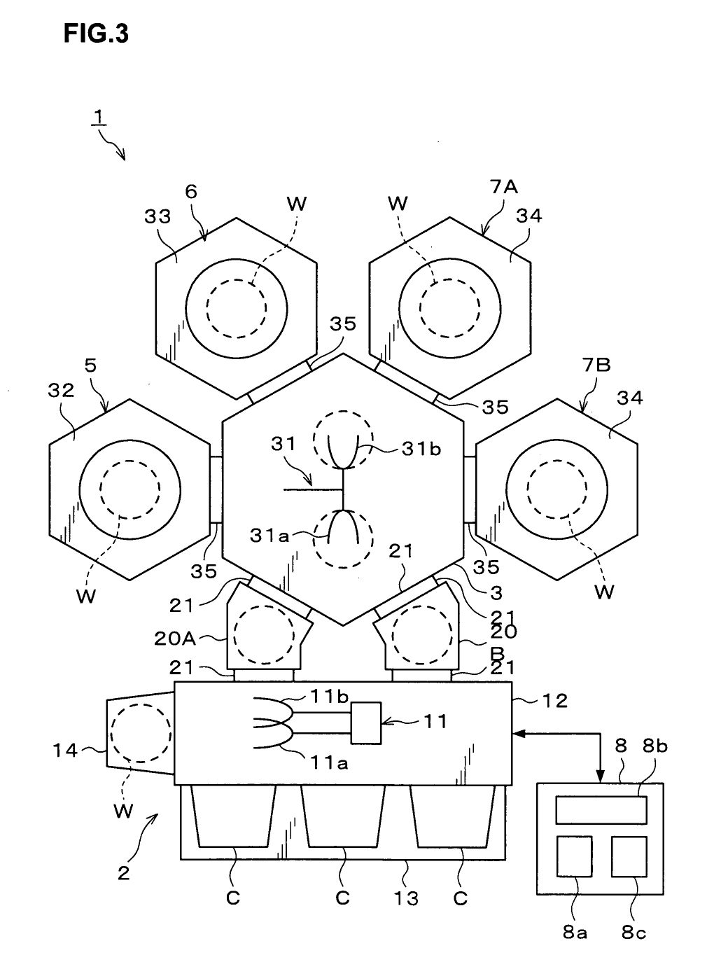

Next, a processing system applying a COR process, a PHT process, and a SiGe layer forming process to the wafer W which has been etched will be described. A processing system 1 shown in FIG. 3 includes: a load/unload unit 2 loading/unloading the wafer W to/from the processing system 1; a common transfer chamber (transfer chamber) 3 formed in a substantially polygonal shape (a hexagonal shape, for instance); a COR apparatus 5 as a substrate processing apparatus applying the COR (Chemical Oxide Removal) process to the wafer W; a PHP apparatus 6 as a substrate processing apparatus applying the PHT (Post Heat Treatment) process to the wafer W; a plurality of, for example, two, epitaxial growth apparatuses 7A, 7B as substrate processing apparatuses performing the SiGe layer forming process; and a control computer 8 giving control commands to the respective parts of the processing system 1.

The load/unload unit 2 has a transfer chamber 12 in which a first wafer carrier mechanism 11 carrying the wafer W in, for example, a substantially disk shape is provided. The wafer carrier mechanism 11 has two carrier arms 11a, 11b each holding the wafer W in a substantially horizontal state. On a side of the transfer chamber 12, there are, for example, three mounting tables 13 on which carriers C each capable of housing the plural wafers W are mounted. An orienter 14 which rotates the wafer W and optically calculates its eccentricity amount to align the wafer W is provided in the load/unload unit 2.

The transfer chamber 12 and the common transfer chamber 3 are coupled to each other via two load lock chambers 20A, 20B which can be evacuated. Openable/closable gate valves 21 are provided between the load lock chambers 20A, 20B and the transfer chamber 12 and between the load lock chambers 20A, 20B and the common transfer chamber 3. One of the two load lock chambers 20A, 20B (for example, the load lock chamber 20A) may be used when the wafer W is carried out of the transfer chamber 12 to be carried into the common transfer chamber 3, and the other (for example, the load lock chamber 20B) may be used when the wafer W is carried out of the common transfer chamber 3 to be carried into the transfer chamber 12.

In the load/unload unit 2 as structured above, the wafer W is held by either of the carrier arms 11a, 11b, and when the wafer carrier mechanism 11 is driven, the wafer W is rotated and moved straight in a substantially horizontal plane or lifted up/down to be carried to a desired position. Then, by the carrier arms 11a, 11b entering or exiting from the carriers C on the mounting table 10, the orienter 12, and the load lock chambers 20A, 20B, the wafers W are carried thereto/therefrom.

A second wafer carrier mechanism 31 carrying the wafer W is provided in the common transfer chamber 3. The wafer carrier mechanism 31 has two carrier arms 31a, 31b each holding the wafer W in a substantially horizontal state.

On an outer side of the common transfer chamber 3, the COR apparatus 5, the PHP apparatus 6, the epitaxial growth apparatus 7A, the epitaxial growth apparatus 7B, the load lock chamber 20B, and the load lock chamber 20A are disposed in this order in a clockwise direction when seen from above, for instance, so as to surround the common transfer chamber 3. Openable/closable gate valves 35 are provided between the common transfer chamber 3 and a processing chamber 32 in the COR apparatus 5, between the common transfer chamber 3 and a processing chamber 33 in the PHP apparatus 6, and between the common transfer chamber 3 and processing chambers 34 in the epitaxial growth apparatuses 7A, 7B.

In the common transfer chamber 3 as structured above, the wafer W is held by either of the carrier arms 31a, 31b, and when the wafer carrier mechanism 31 is driven, the wafer W is rotated and moved straight in a substantially horizontal plane or lifted up/down to be carried to a desired position. Then, by the carrier arms 31a, 31b entering and exiting from the load lock chambers 20A, 20B, the processing chamber 32 in the COR apparatus 5, the processing chamber 33 in the PHT apparatus 6, and the processing chambers 34 in the epitaxial growth apparatuses 7A, 7B, the wafers W are loaded/unloaded to/from the respective processing chambers.

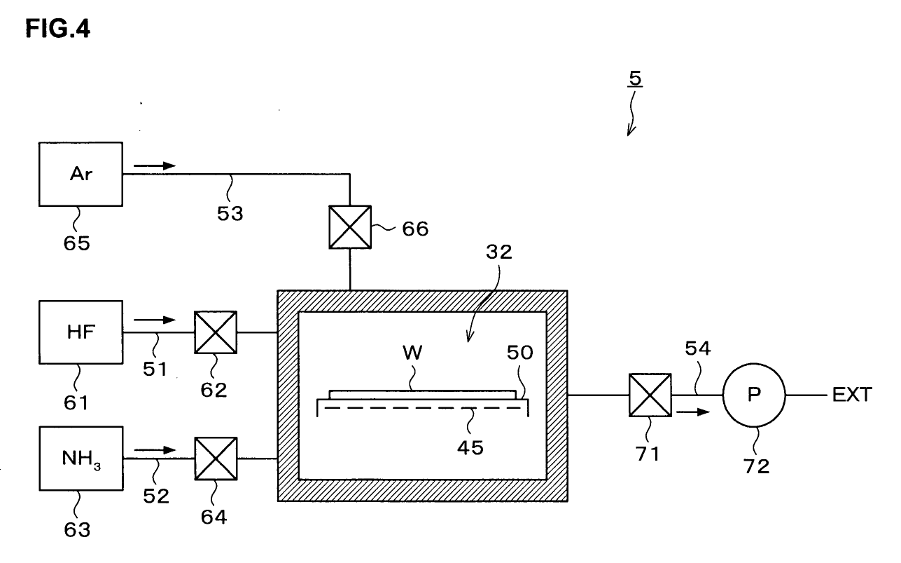

As shown in FIG. 4, the COR apparatus 5 includes the airtightly closed processing chamber (processing space) 32 housing the wafer W, and in the processing chamber 32, a mounting table 50 holding the wafer W substantially horizontally is provided. In the mounting table 50, a temperature regulator 45 regulating the temperature of the wafer W is provided. The temperature regulator 45 is composed of a heater provided in the mounting table 50, a heat medium circulation channel, and so on, and regulates the temperature of the wafer W placed on the mounting table 50 when supplied with power, the heat medium, and so on. On a side of the processing chamber 32, a load/unload port (not shown) through which the wafer W is loaded/unloaded into/out of the processing chamber 32 is provided, and the aforesaid gate valve 35 is provided in this load/unload port.

The COR apparatus 5 further includes: a supply path 51 through which hydrogen fluoride gas (HF) as process gas containing a halogen element is supplied to the processing chamber 32; a supply path 52 through which ammonia gas (NH₃) as basic gas is supplied to the processing chamber 32; a supply path 53 through which inert gas such as argon gas (Ar) as process gas or dilution gas is supplied to the processing chamber 32; and an exhaust path 54 through which the atmosphere in the processing chamber 32 is discharged. The supply path 51 is coupled to a supply source 61 of the hydrogen fluoride gas. Further, in the supply path 51, a flow rate regulating valve 62 capable of opening/closing the supply path 51 and regulating a supply flow rate of the hydrogen fluoride gas is provided. The supply path 52 is coupled to a supply source 63 of the ammonia gas. Further, in the supply path 52, a flow rate regulating valve 64 capable of opening/closing the supply path 53 and regulating a supply flow rate of the argon gas is provided. The supply path 53 is coupled to a supply source 65 of the argon gas. Further, in the supply path 53, a flow rate regulating valve 66 capable of opening/closing the supply path 53 and regulating a supply flow rate of the argon gas is provided In the exhaust path 54, an opening/closing valve 71 and an exhaust pump 72 for forced exhaust are provided.

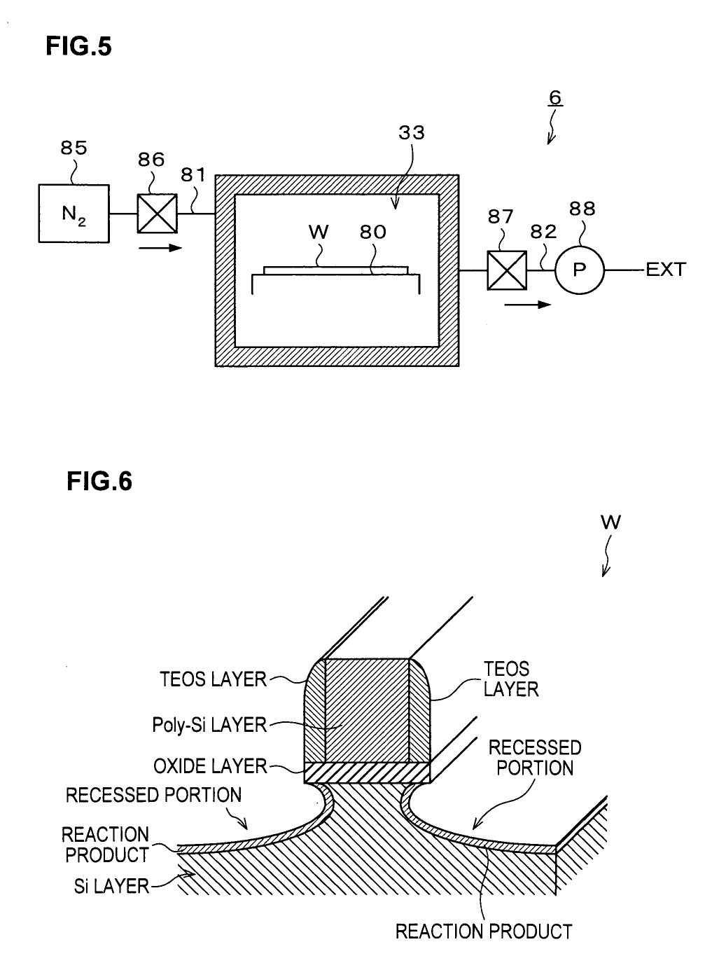

As shown in FIG. 5, the PHT apparatus 6 includes the airtightly closed processing chamber (processing space) 33 housing the wafer W, and in the processing chamber 33, a mounting table 80 holding the wafer W substantially horizontally is provided. Further, a load/unload port, not shown, through which the wafer W is loaded/unloaded into/out of the processing chamber 33 is provided, and the aforesaid gate valve 35 is provided in this load/unload port.

The PHP apparatus 6 further includes: a supply path 81 through which heated inert gas such as, for example, nitrogen gas (N₂) is supplied to the processing chamber 33; and an exhaust path 82 through which the atmosphere in the processing chamber 33 is discharged. The supply path 81 is coupled to a supply source 85 of the nitrogen gas. Further, a flow rate regulating valve 86 capable of opening/closing the supply path 81 and regulating a supply flow rate of the nitrogen gas is provided in the supply path 81. An opening/closing valve 87 and an exhaust pump 88 for forced exhaust are provided in the exhaust path 82.

The functional elements of the processing system 1 are coupled via a signal line to a control computer 8 automatically controlling the operation of the whole processing system 1. Here, the functional elements refer to all the elements which operate for realizing predetermined process conditions, such as, for example, the aforesaid gate valve 35, temperature regulator 45, flow rate regulating valves 62, 64, 66, opening/closing valve 71, and exhaust pump 72 of the COR apparatus 5, the aforesaid gate valve 35, flow rate regulating valve 86, and exhaust pump 88 of the PHT apparatus 6, and so on. The control computer 8 is typically a general-purpose computer capable of realizing arbitrary functions depending on software that it executes.

As shown in FIG. 3, the control computer 8 has an arithmetic unit 8a including a CPU (central processing unit), an input/output unit 8b coupled to the arithmetic unit 8a, and a recording medium 8c inserted in the input/output unit 8b and storing control software. The recording medium 8c contains recorded control software (program) which causes the processing system 1 to perform a later-described predetermined substrate processing method when executed by the control computer 8. The control computer 8 executes the control software to control the functional elements of the processing system 1 so that various process conditions (for example, pressure of the processing chamber 32 and so on) defined by a predetermined recipe are realized.

The recording medium 8c may be a medium fixedly provided in the control computer 8, or may be a medium removably attached to a not-shown reader provided in the control computer 8 to be readable by the reader. In the most typical embodiment, the recording medium 8c is a hard disk drive containing the control software installed by a serviceman of a maker of the processing system. In another embodiment, the recording medium 8c is a removable disk such as CD-ROM or DVD-ROM in which the control software is written. Such a removable disk is read by an optical reader (not shown) provided in the control computer 8. Further, the recording medium 8c may be either of a RAM (random access memory) type or a ROM (read only memory) type. Further, the recording medium 8c may be a cassette-type ROM. In short, any medium known in a computer technical field is usable as the recording medium 8c. In a factory where the plural processing systems 1 are disposed, the control software may be stored in a management computer centrally controlling the control computers 8 of the processing systems 1. In this case, each of the processing systems 1 is operated by the management computer via a communication line to execute a predetermined process.

Next, a method of processing the wafer W using the processing system 1 as configured above will be described. First, the wafer W which has the Si layer, the oxide layer, the Poly-Si layer, and the TEOS layers as shown in FIG. 1 is subjected to a dry etching process by a dry etching apparatus or the like, and the recessed portions where Si is exposed are formed as shown in FIG. 2. The wafer W having undergone the dry etching process is housed in the carrier C to be carried to the processing system 1. The wafer W thus carried to the processing system 1 has the natural oxide films (SiO₂) which are formed on the inner surfaces of the recessed portions when oxygen in the atmosphere adheres on the surface of Si exposed in the recessed portions, as shown in FIG. 2.

In the processing system 1, as shown in FIG. 3, the carrier C housing the plural wafers W is placed on the mounting table 13, and one of the wafers W is taken out of the carrier C by the wafer carrier mechanism 11 to be carried into the load lock chamber 20A. When the wafer W is carried into the load lock chamber 20A, the load lock chamber 20A is airtightly closed and pressure-reduced. Thereafter, the load lock chamber 20A and the common transfer chamber 3 whose pressure is reduced below the atmospheric pressure are made to communicate with each other. Then, the wafer W is carried out of the load lock chamber 20A to be carried into the common transfer chamber 3 by the wafer carrier mechanism 31.

The wafer W carried into the common transfer chamber 3 is first carried into the processing chamber 32 of the COR apparatus 5. The wafer W is held in the processing chamber 32, with its front surface (device formation surface) facing upward. The processing chamber 32 is airtightly closed when the wafer W is carried thereto, and the COR process is started. In the COR process, the temperature regulator 45 regulates the temperature of the wafer W placed on the mounting table 50, and at the same time, the atmosphere in the processing chamber 32 is forcedly discharged through the exhaust path 54, and while the inside of the processing chamber 32 is kept at a predetermined reduced pressure which is lower than the atmospheric pressure, the hydrogen fluoride gas and the ammonia gas are supplied into the processing chamber 32 through the supply paths 51, 52 at predetermined flow rates respectively. As a result of the supply of the hydrogen fluoride gas and the ammonia gas under the reduced pressure, the natural oxide films formed on the inner surfaces of the recessed portions of the wafer W chemically react with molecules of the hydrogen fluoride gas and molecules of the ammonia gas. As a result, the natural oxide films on the recessed portions are turned into reaction products mainly made of ammonium fluosilicate ((NH₄)₂SiF₆) (see FIG. 6). In this manner, the wafer W in the processing chamber 32 undergoes the COR process, so that the reaction products are produced on the inner surfaces of the recessed portions.

Under predetermined conditions where the pressure and the temperature are regulated, the chemical reaction with the hydrogen fluoride gas and the ammonia gas actively occurs selectively in the natural oxide films of the wafer W, and does not occur so actively in the other layers (Si layer, the oxide layer, the Poly-Si layer, the TEOS layers, and so on) as it occurs in the natural oxide films. Therefore, it is possible to selectively cause the natural oxide film, which is an object to be removed, to chemical react while suppressing the occurrence of the chemical reaction of the other layers. The pressure in the processing chamber 32 is regulated by the opening degrees of the flow rate regulating valves 62, 64, an exhaust flow rate of the exhaust pump 72, and so on. The temperature of the wafer W (temperature of the Si layer) is regulated by the temperature regulator 45 of the mounting table 50. Further, a mixing ratio and a partial pressure ratio of the hydrogen fluoride gas and the ammonia gas in the processing chamber 32 are also controlled to predetermined values by the regulation of the supply flow rates of these gases.

When the COR process is finished, the supply of the hydrogen fluoride gas and the ammonia gas through the supply paths 51, 52 is stopped. Then, the argon gas is supplied through the supply path 53, so that the inside of the processing chamber 32 is purged by the argon gas. Thereafter, the load/unload port of the COR apparatus 5 is opened to make the processing chamber 32 and the common transfer chamber 3 communicate with each other. The wafer W is carried out of the processing chamber 32 by the wafer carrier mechanism 31 to be carried into the processing chamber 33 of the PHT apparatus 6.

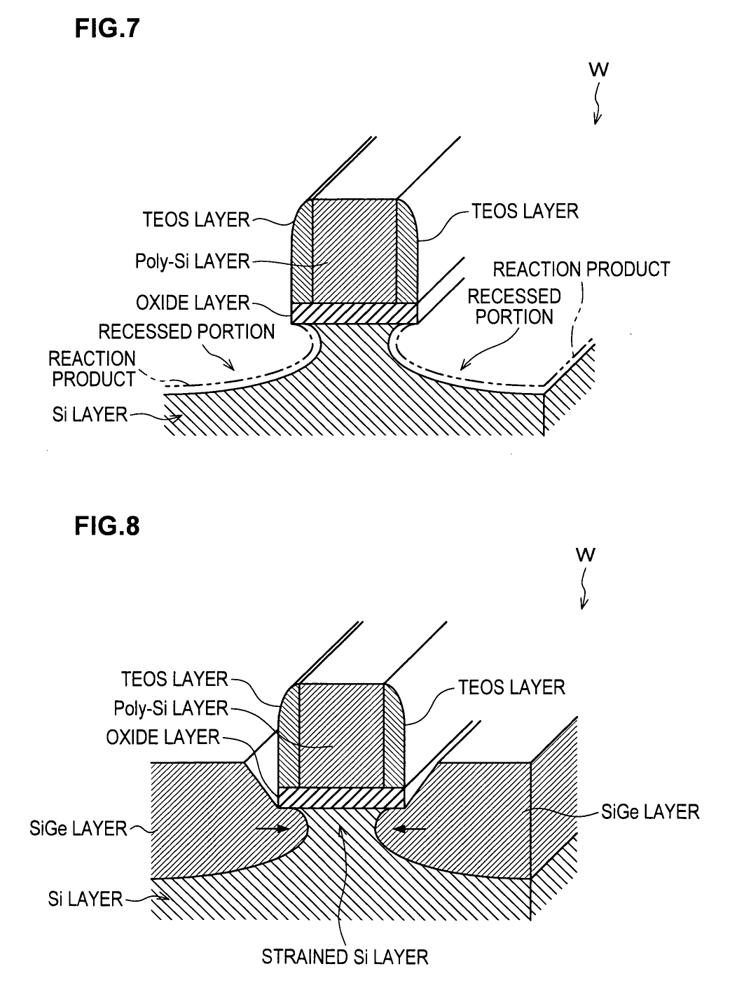

In the PHT apparatus 6, the wafer W is held in the processing chamber 33 with its front surface facing upward. The processing chamber 33 is airtightly closed when the wafer W is carried thereto, and the PHT process is started. In the PHT process, while the atmosphere in the processing chamber 33 is discharged through the exhaust path 82, the high-temperature heating gas is supplied into the processing chamber 33 through the supply path 81, and the heating gas increases the temperature in the processing chamber 33. Consequently, the reaction products produced by the aforesaid COR process are heated and vaporized to be removed from the inner surfaces of the recessed portions, so that the surface of the Si layer is exposed (see FIG. 7). The temperature and pressure in the processing chamber 33 are controlled to conditions under which the reaction products vaporize, that is, the processing chamber 33 is heated to a temperature equal to about 100° C. or higher, for instance. By thus undergoing the PHT process after the COR process, the wafer W can be dry-cleaned, so that the natural oxide films can be removed from the Si layer by dry etching.

When the PHT process is finished, the supply of the heating gas is stopped, and the load/unload port of the PHT apparatus 6 is opened. Thereafter, the wafer W is carried out of the processing chamber 33 by the wafer carrier mechanism 31 to be carried into the processing chamber 34 of the epitaxial growth apparatus 7A or 7B. During the transfer of the wafer W from the PHT apparatus 6 to the epitaxial growth apparatus 7A or 7B, internal parts of the processing chamber 33, the common transfer chamber 3, and the processing chamber 34 are kept in an atmosphere of inert gas such as nitrogen gas or in a vacuum state, and an oxidizing atmosphere is discharged. Therefore, there is no risk of the wafer W being exposed to oxygen, which can prevent the re-production of the natural oxide films on the Si layer.

When the wafer W is carried into the processing chamber 34, the processing chamber 34 is airtightly closed, and the SiGe film formation process is started. In the film formation process, reaction gas supplied into the processing chamber 34 and the Si layer exposed in the recessed portions of the wafer W chemically react with each other, so that SiGe epitaxially grows on the recessed portions (see FIG. 8). Here, since the natural oxide films have been removed by the aforesaid COR process and PHT process from the surface of the Si layer exposed in the recessed portions, SiGe is suitably grown on the surface of the Si layer as its base.

When the SiGe layers are formed on the both recessed portions, a portion, of the Si layer, sandwiched by the SiGe layers is given a compressive stress. That is, under the Poly-Si layer and the oxide layer, a strained Si layer having a compressive strain is formed in the portion sandwiched by the SiGe layers.

When the SiGe layers are thus formed, that is, when the film forming process is finished, the wafer W is carried out of the processing chamber 34 by the wafer carrier mechanism 31 to be carried into the load lock chamber 20B. When the wafer W is carried into the load lock chamber 20B, the load lock chamber 20B is airtightly closed, and thereafter, the load lock chamber 20B and the transfer chamber 12 are made to communicate with each other. Then, the wafer W is carried out of the load lock chamber 20B to be returned to the carrier C on the mounting table 13, by the wafer carrier mechanism 11. In the above-described manner, a series of the processes in the processing system 1 is finished.

According to such a processing method, the natural oxide films are removed by the dry cleaning process including the COR process and the PHT process, which makes it possible to reduce a damage given to parts other than the natural oxide films, such as, for example, the Si layer, the oxide layer, the Poly-Si layer, and the TEOS layers. Further, it is possible to epitaxially grow the SiGe layers with good film quality on the Si layer without roughening the crystal structure of the surface of the Si layer from which the oxide film has been removed. Therefore, the structure of the semiconductor device can be surely manufactured.

In the dry cleaning process including the COR process and the PHT process, a damage given to the Si layer, the oxide layer, the Poly-Si layer, the TEOS layers, and the like can be reduced, but on the other hand, the dry cleaning process has a drawback that its speed of removing the Si oxide films is lower than that of wet cleaning using a treatment solution such as DHF. Therefore, parts of the oxide films growing on the surface of the Si layer may be removed in advance by wet etching using a treatment solution, and thereafter, the remaining parts of the oxide films, the parts of which have been removed by the wet etching, may be removed by the dry cleaning process including the COR process and the PHP process.

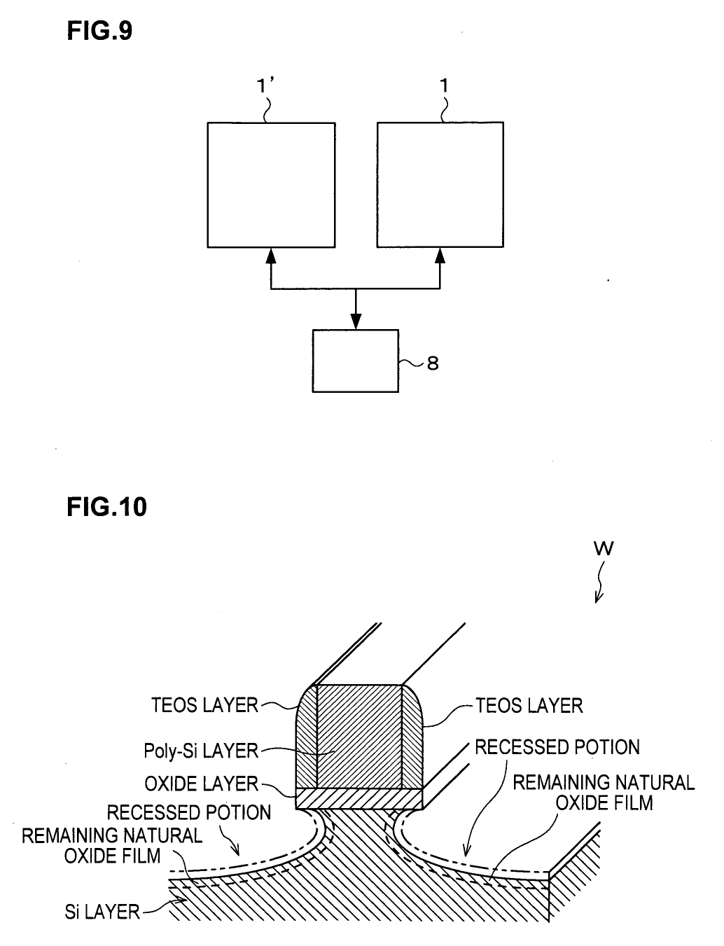

FIG. 9 is an explanatory view of a system group including a processing system 1′ performing the wet etching using a treatment solution, in addition to a processing system 1 performing the dry cleaning process including the COR process and the PHT process. The processing system 1 included in the system group is the same as the processing system 1 previously described in FIGS. 3 to 6. The processing system 1 includes a COR apparatus 5 applying the COR (Chemical Oxide Removal) process to the wafer W, a PHT apparatus 6 applying the PHT (Post Heat Treatment) process to the wafer W, an epitaxial growth apparatus 7 applying the SiGe layer forming process, and so on. Further, the processing system 1′ included in the system group is capable of removing the oxide films growing on the surface of the Si layer by wet etching using a treatment solution such as DHF. As the processing system 1′, a conventionally and generally known wet treatment system can be used. In the system group, the processing system 1 and the processing system 1′ are controlled by a control computer 8. The structure of the control computer 8 is the same as that of the control computer 8 previously described in FIG. 3, and the constituent elements included in the processing system 1 and the processing system 1 are controlled by the control computer 8.

A method of processing the wafer W in the system group shown in FIG. 9 will be described. First, the wafer W having the Si layer, the oxide layer, the Poly-Si layer, and the TEOS layers as shown in FIG. 1 is subjected to an etching process by a dry etching apparatus or the like, and the recessed portions from which Si is exposed are formed as shown in FIG. 2. The wafer W after undergoing such dry etching process is housed in the carrier C to be carried to the processing system P. As shown in FIG. 2, the wafer W thus carried to the processing system 1′ has the natural oxide films (SiO₂) which have been formed on the inner surfaces of the recessed portions when oxygen in the atmosphere adheres to the surface of Si exposed in the recessed portions.

Next, in the processing system 1′, parts of the natural oxide films growing on the surface of the Si layer are removed by the wet etching using the treatment solution such as DHF. As a result of the removal of the parts of the natural oxide films formed on the inner surfaces of the recessed portions of the wafer W, the remaining parts of the natural oxide films, the parts of which have been removed by the wet etching, exist on the inner surfaces of the recessed portions as shown in FIG. 10.

Then, the wafer W having the remaining parts of the natural oxide films existing on the inner surfaces of the recessed portions of the wafer W is carried out of the processing system 1′ and is housed in the carrier C, and is carried to the processing system 1. Next, in the processing system 1, the COR process, the PHT process, and the epitaxial growth are performed in this order as in the above-described case. Specifically, in the COR apparatus 5 included in the processing system 1, the gas containing the halogen element and the basic gas are supplied to the surface of the wafer W, so that the remaining parts of the natural oxide films existing on the inner surfaces of the recessed portions of the wafer W chemically react with the gas containing the halogen element and the basic gas. As a result, the remaining parts of the oxide films are turned into the reaction products (see FIG. 6). Next, in the PHT apparatus 6, the wafer W is heated, so that the reaction products produced by the COR process are vaporized due to the heating to be removed from the inner surfaces of the recessed portions, and as a result, the surface of the Si layer is exposed (see FIG. 7). Thereafter, in the epitaxial growth apparatus 7, the SiGe film forming process is started, so that SiGe epitaxially grows on the recessed portions (see FIG. 8).

According to the processing method in the processing system group shown in FIG. 9, parts of the oxide films growing on the surface of the Si layer are removed in advance by the wet etching using the treatment solution, and thereafter, the remaining parts of the oxide films are removed by the dry cleaning process including the COR process and the PHT process, which makes it possible to shorten the processing time. Further, since the dry cleaning process including the COR process and the PHT process is performed after the wet etching using the treatment solution, it is possible to epitaxially grow the SiGe layers with good film quality on the Si layer without roughening the crystal structure of the surface of the Si layer from which the oxide films have been removed.

In the foregoing, a preferred embodiment of the present invention is described, but the present invention is not limited to such an example. It is obvious that those skilled in the art could reach various modified examples and corrected examples within the range of the technical idea described in the claims, and it should be understood that these examples naturally belong to the technical scope of the present invention.

The sidewall portions are made of TEOS as an example, but this TEOS may be TEOS whose film is formed by a plasma CVD apparatus (plasma-TEOS), or may be TEOS whose film is formed by a thermal CVD apparatus (LP-TEOS). Further, the material of the sidewall portions is not limited to TEOS and may be SiN (silicon nitride), for instance. SiN of the sidewall portions may be SiN whose film is formed by a plasma CVD apparatus (plasma-SiN) or may be SiN whose film is formed by a thermal CVD apparatus (LP-SiN). A selection ratio of any of these materials in the COR process and the PHT process is lower than that of the natural oxide films and thus these materials are less likely to be damaged when the natural oxide films are removed. Therefore, it is possible to surely form the structure of a semiconductor device.

As an example, the description is given of the wafer W in which Si is exposed by the etching process in advance before the wafer W is carried into the processing system 1, but the present invention is applicable to the wafer W which further undergoes chemical solution treatment using H₂SO₄ or H₂O₂, chemical solution treatment using NH₃OH or H₂O₂, chemical solution treatment using HCl or H₂O₂, organic chemical solution treatment, or the like after the etching process. Further, the present invention is applicable to the COR process of an oxide film other than the natural oxide film.

In the above-described embodiment, the inert gas supplied as the process gas or the dilution gas to the processing chamber 32 of the COR apparatus 5 is the argon gas, but this inert gas may be other inert gas, for example, may be any of nitrogen gas (N2), helium gas (He), and xenon gas (Xe), or may be mixed gas of any two kinds of argon gas, nitrogen gas, helium gas, and xenon gas.

Further, in the above-described embodiment, the SiGe layers are formed by the epitaxial growth apparatus, but a CVD apparatus may be used for such a film forming process.

The above embodiment describes the processing method in which the wafer W successively undergoes the COR process, the PHT process, and the film forming process in the processing system 1 in which the COR apparatus 5, the PHT apparatus 6, and the epitaxial growth apparatuses 7A, 7B are coupled to the common transfer chamber 3, but needless to say, the processing method according to the present invention is not limited to that performed by the processing system 1 described above. For example, a first processing system in which the COR apparatus and the PHP apparatus are coupled to the common transfer chamber and another second processing system including an epitaxial growth apparatus may be provided and these first processing system and the second processing system may be used in the processing method. Specifically, the procedure of the method may be as follows: the wafer W having undergone the dry etching process is housed in the carrier C to be carried to the first processing system, where the wafer W is taken out from the carrier C and undergoes the COR process and the PHT process, and then the wafer W is returned to the carrier C again, and the whole carrier C is carried to the second processing system, where the wafer W is taken out from the carrier C and is subjected to the film forming process by the epitaxial growth apparatus.

The example is described where, after undergoing the COR process in the COR apparatus 5, the wafer W is carried to the PHT apparatus 6 to undergo the PHT process there, but for example, after undergoing the COR process in the COR apparatus 5, the wafer may be kept stayed there to undergo the PHT process in the COR apparatus 5.

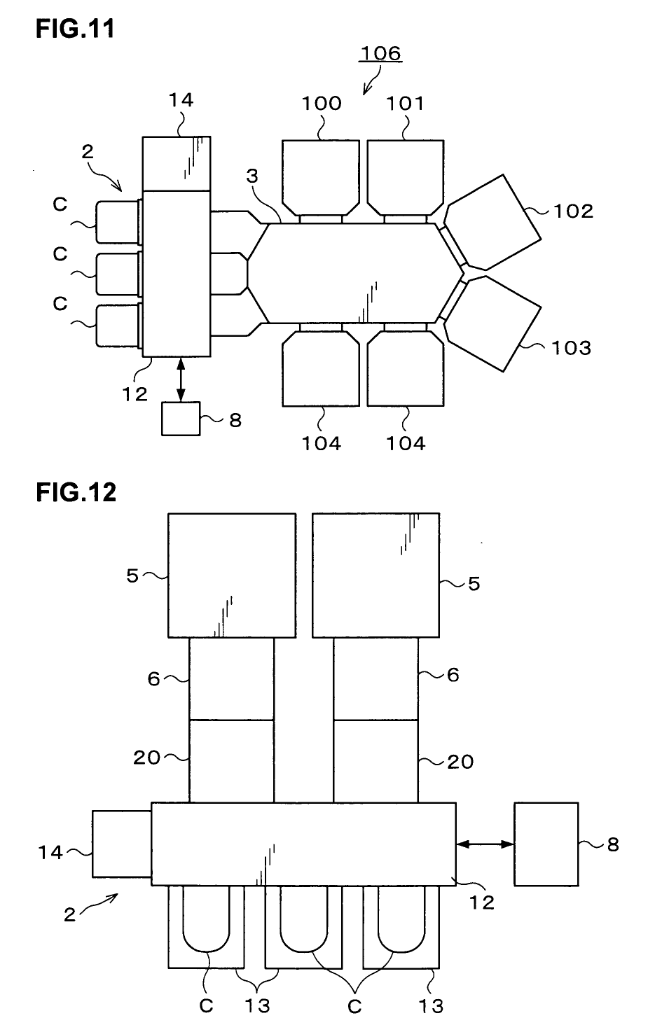

The present invention is applicable not only to the processing system 1 shown in FIG. 3 and the processing system group shown in FIG. 9 but also to a processing system 106 including six processing apparatuses 100 to 105 around a common transfer chamber 3 as shown in FIG. 11, for instance. Further, the present invention is applicable to a processing system 110 in which the wafer W is carried to a COR apparatus 5 from a load/unload unit 2 via a load lock chamber 20 and a PHT apparatus 6, and the wafer W is processed in the COR apparatus 5 and the PHT apparatus 6 in this order as shown in FIG. 12, for instance. Any number of the processing apparatuses may provided in the processing system and they may be arranged in an arbitrary manner.

### Example

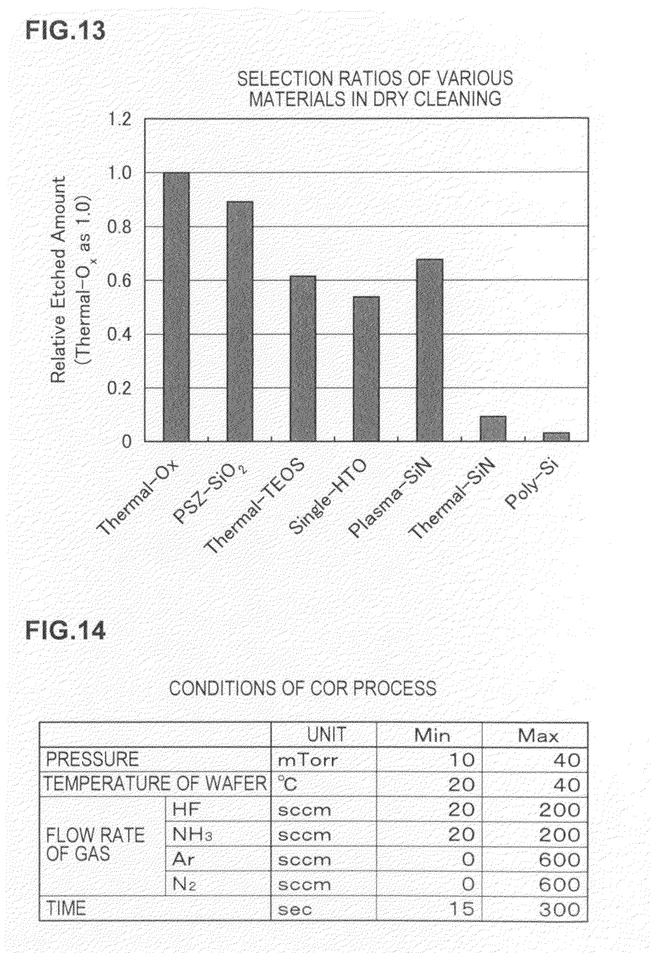

The present inventors studied selection ratios as removal amounts regarding various materials used in the manufacture of a semiconductor device when the dry cleaning (etching) including the COR process and the PHT process was performed. FIG. 13 is a graph showing the result of the study. The selection ratio was obtained as a ratio relative to a removal amount of a thermal oxide film (Thermal-Ox) which is defined as 1. The selection ratios of the following six kinds of materials were studied: a polysilazane oxide film (PSZ-SiO2), a thermal CVD oxide film (Thermal-TEOS), a HTO film (Single-HTO), a plasma silicon nitride (plasma-SiN), a thermal CVD nitride film (Thermal-SiN), polysilicon (Poly-Si). As a result, the selection ratios were all 1 or lower. Therefore, it was confirmed that any of the materials is more difficult to chemically react in the COR process than the thermal oxide film (Thermal-Ox) and is not easily damaged by the dry cleaning. That is, it was confirmed that the natural oxide film as an object to be removed can be selectively removed.

Further, the present inventors studies various conditions of the COR process in this embodiment. FIG. 14 shows an example of a range of preferable numerical values of the various conditions. It is desirable that pressure of the atmosphere in the processing chamber when the hydrogen fluoride gas and the ammonia gas are supplied is not lower than 10 mTorr (about 1.33 Pa) nor higher than 40 mTorr (about 5.34 Pa), and temperature of the wafer (that is, temperature of the Si layer) is not lower than 20° C. nor higher than 40° C. Further, it is desirable that, while the hydrogen fluoride gas is supplied at a supply flow rate of not lower than 20 sccm (about 3.38×10⁻² m³/s) nor higher than×200 sccm (about 33.8×10^{˜-2} m³/s), the ammonia gas is supplied at a supply flow rate of not lower than 20 sccm nor higher than 200 sccm. Further, the processing time during which these supply flow rate, pressure, temperature conditions are maintained is preferably not shorter than 15 seconds nor longer than 300 seconds. Further, argon gas (Ar) and/or nitrogen gas (N₂) may be supplied together with the hydrogen fluoride gas and the ammonia gas. In this case, it is preferable that the argon gas is supplied at 600 sccm (about 101.4×10⁻² m³/s) or lower and the nitrogen gas is supplied at 600 sccm or lower.

### INDUSTRIAL APPLICABILITY

The present invention is applicable to a method of forming a SiGe layer on a Si layer of a wafer in manufacturing processes of, for example, a semiconductor device and to a recording medium.

1. A processing method for removing an oxide film growing on a surface of a Si layer, and forming a SiGe layer on the surface of the exposed Si layer, the method comprising:
supplying gas containing a halogen element and basic gas to the surface of the Si layer, and causing the oxide film growing on the surface of the Si layer to chemically react with the gas containing the halogen element and the basic gas to turn the oxide film into a reaction product;
removing the reaction product by heating; and
thereafter forming the SiGe layer on the surface of the exposed Si layer.

2. The processing method according to claim 1, wherein part of the Si layer is exposed in advance by dry-etching an interlayer insulation layer after the formation of the interlayer insulation layer on the Si layer.

3. The processing method according to claim 2, wherein a gate electrode is formed on the interlayer insulation layer.

4. The processing method according to claim 3, wherein a sidewall portion is formed on a side surface of the gate electrode.

5. The processing method according to claim 1, wherein the gas containing the halogen element is hydrogen fluoride gas, and the basic gas is ammonia gas.

6. The processing method according to claim 5, wherein the hydrogen fluoride gas is supplied at not lower than 20 sccm nor higher than 200 sccm.

7. The processing method according to claim 5, wherein the ammonia gas is supplied at not lower than 20 sccm nor higher than 200 sccm.

8. The processing method according to claim 1, wherein argon gas is supplied at 600 sccm or lower in the process of causing the chemical reaction.

9. The processing method according to claim 1, wherein nitrogen gas is supplied at 600 sccm or lower in the process of causing the chemical reaction.

10. The processing method according to any one of claim 1, wherein pressure of a processing space where the process of causing the chemical reaction is performed is not lower than 1.333 Pa nor higher than 5.333 Pa.

11. The processing method according to any one of claim 1, wherein temperature of the Si layer is not lower than 20° C. nor higher than 40° C. in the process of causing the chemical reaction.

12. The processing method according to claim 1, wherein processing time for the chemical reaction is not shorter than 15 seconds nor longer than 300 seconds.

13. A processing method for removing an oxide film growing on a surface of a Si layer when a SiGe layer is to be formed on the surface of the Si layer, the method comprising:
supplying gas containing a halogen element and basic gas to the surface of the Si layer, and causing the oxide film growing on the surface of the Si layer to chemically react with the gas containing the halogen element and the basic gas to turn the oxide film into a reaction product; and
removing the reaction product by heating.

14. The processing method according to claim 13, wherein part of the Si layer is exposed in advance by dry-etching an interlayer insulation layer after the formation of the interlayer insulation layer on the Si layer.

15. The processing method according to claim 14, wherein a gate electrode is formed on the interlayer insulation layer.

16. The processing method according to claim 15, wherein a sidewall portion is formed on a side surface of the gate electrode.

17. The processing method according to claim 13, wherein the gas containing the halogen element is hydrogen fluoride gas, and the basic gas is ammonia gas.

18. The processing method according to claim 17, wherein the hydrogen fluoride gas is supplied at not lower than 20 sccm nor higher than 200 sccm.

19. The processing method according to claim 17, wherein the ammonia gas is supplied at not lower than 20 sccm nor higher than 200 sccm.

20. The processing method according to claim 13, wherein argon gas is supplied at 600 sccm or lower in the process of causing the chemical reaction.

21. The processing method according to claim 13, wherein nitrogen gas is supplied at 600 sccm or lower in the process of causing the chemical reaction.

22. The processing method according to claim 13, wherein pressure of a processing space where the process of causing the chemical reaction is performed is not lower than 1.333 Pa nor higher than 5.333 Pa.

23. The processing method according to claim 13, wherein temperature of the Si layer is not lower than 20° C. nor higher than 40° C. in the process of causing the chemical reaction.

24. The processing method according to claim 13, wherein processing time for the chemical reaction is not shorter than 15 seconds nor longer than 300 seconds.

25. A processing method for removing an oxide film growing on a surface of a Si layer, and forming a SiGe layer on the surface of the exposed Si layer, the method comprising:
removing part of the oxide film growing on the surface of the Si layer by wet etching using a treatment solution;
supplying gas containing a halogen element and basic gas to a remaining part of the oxide film the part of which has been removed by the wet etching, and causing the remaining part of the oxide film to chemically react with the gas containing the halogen element and the basic gas to turn the remaining part of the oxide film into a reaction product;
removing the reaction product by heating; and
thereafter forming the SiGe layer on the surface of the exposed Si layer.

26. A recording medium in which a program executable by a control computer of a substrate processing apparatus is recorded,
the program causing the substrate processing apparatus to perform the substrate processing method according to claim 1 when executed by the control computer.

27. A recording medium in which a program executable by a control computer of a substrate processing apparatus is recorded,
the program causing the substrate processing apparatus to perform the substrate processing method according to claim 13 when executed by the control computer.

28. A recording medium in which a program executable by a control computer of a substrate processing apparatus is recorded,
the program causing the substrate processing apparatus to perform the substrate processing method according to claim 25 when executed by the control computer.
